(19) United States
(12) Patent Application Publication
(10) Pub. No.: US 2026/0196992 A1
(43) Pub. Date: Jul. 9, 2026

(54) CLOCK HARMONICS SPUR REDUCTION AT MULTIPLE FREQUENCIES

(71) Applicant: QUALCOMM Incorporated, San Diego, CA (US)

(72) Inventors: Parisa MAHMOUDIDARYAN, San Diego, CA (US); Andrew WEIL, San Diego, CA (US); Jaswinder SINGH, San Diego, CA (US)

(21) Appl. No.: 19/009,784

(22) Filed: Jan. 3, 2025

(51) Int. Cl. H03K 5/1252; H03K 5/00; H03K 19/21

(52) U.S. Cl. CPC H03K 5/1252; H03K 5/00006; H03K 19/21

(57) ABSTRACT

Certain aspects of the present disclosure are directed towards techniques and apparatus for signal processing. An example apparatus generally includes: a first signal generation path including a first frequency multiplier having an input coupled to a clock node and at least one first tuning circuit coupled to an output of the first frequency multiplier, the at least one first tuning circuit including outputs coupled to a supply node and a reference potential node of the apparatus; and a second signal generation path including a second frequency multiplier having an input coupled to the clock node and at least one second tuning circuit coupled to an output of the second frequency multiplier, the at least one second tuning circuit including outputs coupled to the supply node and the reference potential node of the apparatus.

### TECHNICAL FIELD

Certain aspects of the present disclosure generally relate to electronic devices and, more particularly, to techniques and apparatus for attenuating spur power.

### BACKGROUND

Various electronic circuits operate using a clock signal. The clock signal may be used to synchronize or otherwise control the timing of the operations of circuits in electronic systems. With increased operating speeds, the clock signal frequency has increased in newer generation devices. The rising and falling edges of the clock signal may cause noise at various nodes in the device, which may adversely impact the operations of other circuits.

### SUMMARY

The systems, methods, and devices of the disclosure each have several aspects, no single one of which is solely responsible for its desirable attributes. Without limiting the scope of this disclosure as expressed by the claims that follow, some features will now be discussed briefly. After considering this discussion, and particularly after reading the section entitled “Detailed Description,” one will understand how the features of this disclosure provide the advantages described herein.

Certain aspects of the present disclosure are directed towards an apparatus for signal processing. The apparatus generally includes: a first signal generation path including a first frequency multiplier having an input coupled to a clock node and at least one first tuning circuit coupled to an output of the first frequency multiplier, the at least one first tuning circuit including outputs coupled to a supply node and a reference potential node of the apparatus; and a second signal generation path including a second frequency multiplier having an input coupled to the clock node and at least one second tuning circuit coupled to an output of the second frequency multiplier, the at least one second tuning circuit including outputs coupled to the supply node and the reference potential node of the apparatus.

Certain aspects of the present disclosure are directed towards a method for signal processing. The method generally includes: generating, via a first frequency multiplier, a first frequency-multiplied signal based on a clock signal; tuning the first frequency-multiplied signal to generate a first spur signal on at least one of a supply node or a reference potential node based on the first frequency-multiplied signal; generating, via a second frequency multiplier, a second frequency-multiplied signal based on the clock signal; and tuning the second frequency-multiplied signal to generate a second spur signal on the at least one of the supply node or the reference potential node based on the second frequency-multiplied signal.

Certain aspects of the present disclosure are directed towards an electronic device. The electronic device generally includes: an electronic circuit coupled between a supply node and a reference potential node and configured to perform one or more operations using a clock signal at a clock node, and a spur reduction circuit comprising: a first signal generation path including a first frequency multiplier having an input coupled to the clock node and at least one first tuning circuit coupled to an output of the first frequency multiplier, the at least one first tuning circuit including outputs coupled to a supply node and a reference potential node of the electronic device; and a second signal generation path including a second frequency multiplier having an input coupled to the clock node and at least one second tuning circuit coupled to an output of the second frequency multiplier, the at least one second tuning circuit including outputs coupled to the supply node and the reference potential node of the electronic device.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 illustrates an example device in which aspects of the present disclosure may be implemented.

FIG. 2 illustrates an aggressor circuit coupling spur power to a victim circuit through various paths.

FIG. 3 is an example timing diagram illustrating a four gigahertz (4G) clock, a two gigahertz (2G) clock, and a five hundred megahertz (500M) clock with associated clock spurs.

FIG. 4 illustrates a correction circuit configured to attenuate a clock spur, in accordance with certain aspects of the present disclosure.

FIG. 5 is an example timing diagram illustrating various clock signals and associated spurs.

FIG. 6 illustrates an example implementation of a correction circuit, in accordance with certain aspects of the present disclosure.

FIG. 7 illustrates a multi-path spur reduction circuit using frequency multipliers, in accordance with certain aspects of the present disclosure.

FIG. 8 illustrates a multi-path spur reduction circuit using frequency multipliers to cancel third and fourth harmonic signals, in accordance with certain aspects of the present disclosure.

FIG. 9A illustrates a frequency multiplier for multiplying a frequency of a signal by two and an associated timing diagram, in accordance with certain aspects of the present disclosure.

FIG. 9B illustrates a frequency multiplier for multiplying a frequency of a signal by three or one and a half and an associated timing diagram, in accordance with certain aspects of the present disclosure.

FIG. 10 illustrates example operations for signal processing, in accordance with certain aspects of the present disclosure.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Certain aspects of the present disclosure provide techniques and apparatus for attenuating spur power generated by a clock signal. Certain aspects provide a correction circuit that generates replica clock spurs that are out-of-phase (e.g., by 180°) from clock spurs generated by the clock signal, thereby canceling out (or at least attenuating) the clock spurs. For example, the correction circuit may include a delay circuit that can apply a programmable delay to the clock signal to generate a delay signal. The delay signal may be used to generate the replica clock spurs with power scaling and allows for the phase of the replica clock spurs to be programmable. In some cases replica clock spurs for cancellation may be generated for each of multiple harmonic frequencies using respective replica spur generation paths with frequency multipliers, as described in more detail herein.

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings herein one skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

The word “exemplary” is used herein to mean “serving as an example, instance, or illustration.” Any aspect described herein as “exemplary” is not necessarily to be construed as preferred or advantageous over other aspects.

As used herein, the term “connected with” in the various tenses of the verb “connect” may mean that element A is directly connected to element B or that other elements may be connected between elements A and B (i.e., that element A is indirectly connected with element B). In the case of electrical components, the term “connected with” may also be used herein to mean that a wire, trace, or other electrically conductive material is used to electrically connect elements A and B (and any components electrically connected therebetween).

### An Example Device

It should be understood that aspects of the present disclosure may be used in a variety of applications. Although the present disclosure is not limited in this respect, the circuits disclosed herein may be used in any of various suitable apparatus, such as in the power supply, battery charging circuit, or power management circuit of a communication system, a video codec, audio equipment such as music players and microphones, a television, camera equipment, and test equipment such as an oscilloscope. Communication systems intended to be included within the scope of the present disclosure include, by way of example only, cellular radiotelephone communication systems, satellite communication systems, two-way radio communication systems, one-way pagers, two-way pagers, personal communication systems (PCSs), personal digital assistants (PDAs), Internet of Things (IoT) devices, and the like.

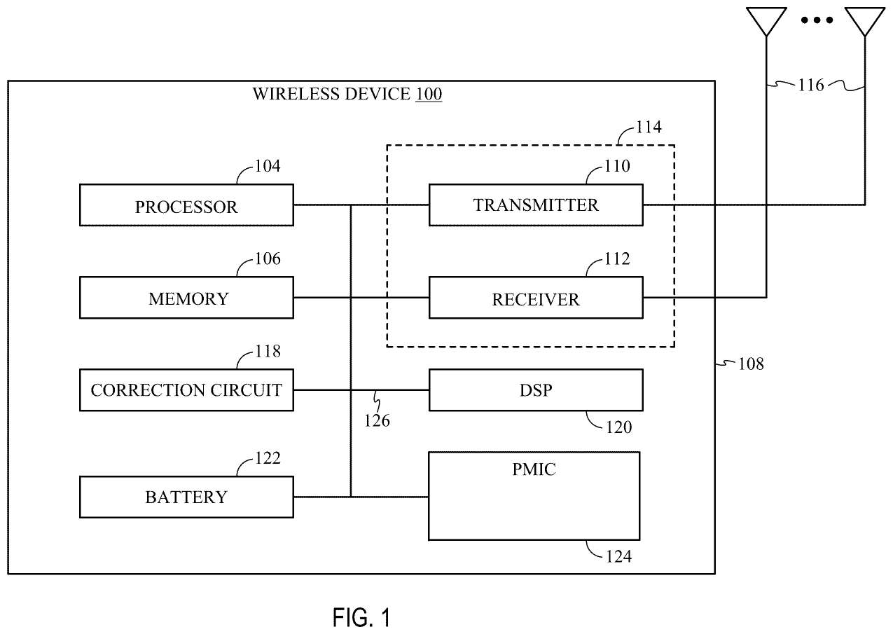

FIG. 1 illustrates an example device 100 in which aspects of the present disclosure may be implemented. The device 100 may be a battery-operated device such as a cellular phone, a PDA, a handheld device, a wireless device, a laptop computer, a tablet, a smartphone, an IoT device, a wearable device, an augmented reality device, etc.

The device 100 may include a processor 104 that controls operation of the device 100. The processor 104 may also be referred to as a central processing unit (CPU). Memory 106, which may include both read-only memory (ROM) and random access memory (RAM), provides instructions and data to the processor 104. A portion of the memory 106 may also include non-volatile random access memory (NVRAM). The processor 104 typically performs logical and arithmetic operations based on program instructions stored within the memory 106.

In certain aspects, the device 100 may also include a transmitter 110 and/or a receiver 112 to allow transmission and/or reception, respectively, of data between the device 100 and a remote location. In some cases, the transmitter 110 and receiver 112 may be combined into a transceiver 114. One or more antennas 116 may be attached or otherwise coupled to a housing 108 of the device 100 and electrically coupled to the transceiver 114. For certain aspects, the device 100 may include multiple transmitters, multiple receivers, and/or multiple transceivers (not shown).

The device 100 may also include a correction circuit 118 that may be used to attenuate clock spur power, as described in more detail herein. The device 100 may also include a digital signal processor (DSP) 120 for use in processing digital signals.

The device 100 may further include a battery 122 used to power the various components of the device 100. The battery 122 illustrated in FIG. 1 may represent multiple portable power sources, such as a main battery and a backup battery (or a supercapacitor). In some cases, the battery 122 may be rechargeable.

The device 100 may also include a power management integrated circuit (PMIC) 124 (also referred to as a “power management unit (PMU)”) for managing the power from the battery 122 to the various components of the device 100, for example. In addition to managing power distribution, the PMIC 124 may perform a variety of other functions for the device, such as DC-to-DC conversion, battery charging, power-source selection, voltage scaling, power sequencing, etc.

The various components of the device 100 may be coupled together by a bus system 126. The bus system 126 may include a power bus, a control signal bus (e.g., system power management interface (SPMI) or inter-integrated circuit (I²C) bus), and/or a status signal bus in addition to a data bus.

### Example Techniques for Clock Spur Reduction

Harmonics of clock signals in mixed-signal, digital, and clock generation circuits create spurs on a supply node, a ground node, and on a substrate that may couple to sensitive parts of a system-on-chip (SoC). This issue is especially prevalent in large-scale SoCs with multiple transmit and receive channels. Spurs on multiple channels experience different transfer functions, adding up and causing hard-to-filter spurs that may couple to sensitive transmit and/or receive ports. This issue is particularly of interest in infrastructures that have stringent emission spur specifications.

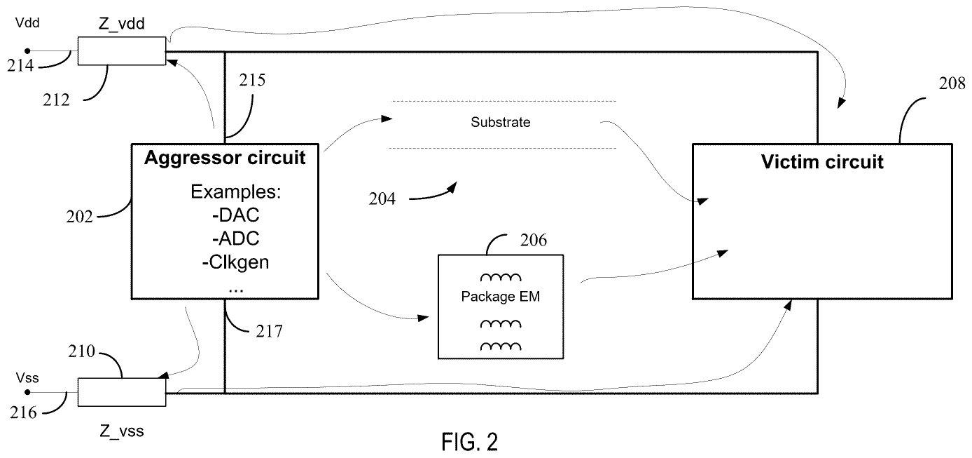

FIG. 2 illustrates an aggressor circuit 202 coupling spur power to a victim circuit 208 through various paths. As shown, the aggressor circuit 202 may be coupled to a supply node 214 receiving a supply voltage (VDD) and a reference potential node 216 (e.g., VSS, also referred to herein as a ground node). As shown, the supply node 214 may include a parasitic impedance 212 (e.g., labeled “Z_vdd”), and the reference potential node 216 may include a parasitic impedance 210 (e.g., labeled “Z_vss”). The parasitic impedance 212 may exist between a supply port 215 (e.g., supply port) of the aggressor circuit 202 and the supply node 214, and the parasitic impedance 210 may exist between a reference potential port 217 (e.g., ground port) of the aggressor circuit 202 and the reference potential node 216.

Spur power from the aggressor circuit 202 may be coupled through the supply node 214, the reference potential node 216, a substrate 204 (on which the circuits 202, 208 are disposed), and/or package electromagnetic (EM) elements 206 (e.g., inductive elements) to the victim circuit 208. The aggressor circuit 202 may be circuitry such as a digital-to-analog converter (DAC), analog-to-digital converter (ADC), or any clock generation circuit. The victim circuit 208 may be a node of a transmitter or receiver in the baseband (BB) domain, intermediate frequency (IF) domain, or a radio frequency (RF) domain.

Typical isolation schemes (e.g., separation of package bumps or balls, separation of package routing, usage of a high-resistive substrate, or usage of guard rings) may be insufficient to meet specifications associated with clock spur emissions. Typical clock spur mitigation schemes involve complex frequency planning to reduce spurs or adjust output power levels that may make system design difficult and/or compromise performance. A finite amount of clock harmonics usually couples to sensitive nets, degrading performance. The clock harmonic spurs may cause hard-to-debug, costly, and difficult-to-fix emissions violations. The specific spur which is challenging to protect against is due to clock harmonics. Different mixed-signal or digital circuits have clock trees that create integer multiples of a clock frequency up to higher order harmonics.

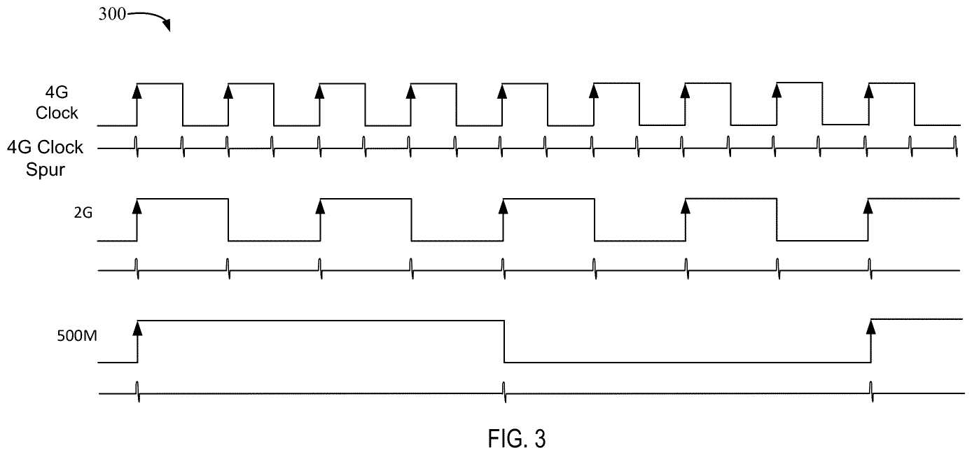

FIG. 3 is an example timing diagram 300 illustrating a four gigahertz (4G) clock, a two gigahertz (2G) clock, and a 500 megahertz (500M) clock and associated clock spurs. As shown, spurs are generated on a supply node or reference potential node at a frequency that is twice the clock frequency (Fclk) (e.g., due to the rising and falling clock edges during each clock cycle). Harmonics of the clock signal are generated at n×Fclk, n being any integer greater than two.

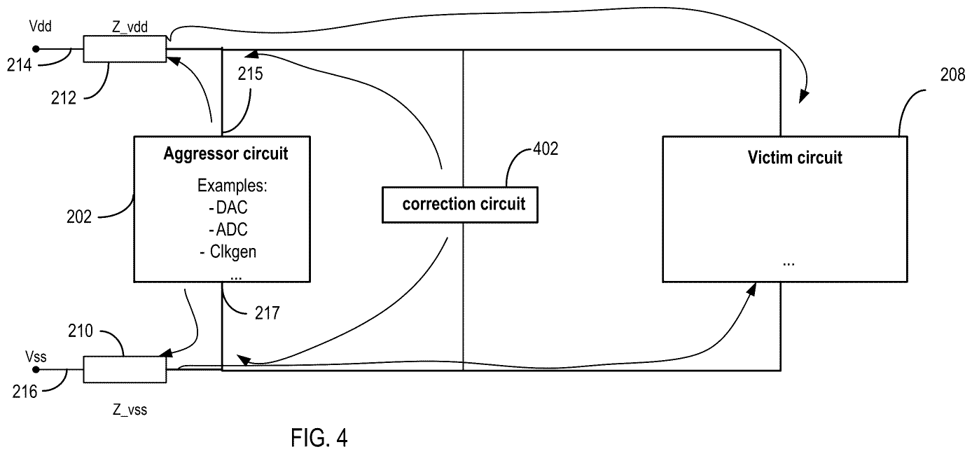

FIG. 4 illustrates a correction circuit 402 configured to attenuate a clock spur, in accordance with certain aspects of the present disclosure. The correction circuit 402 may attenuate the clock spur at a source of the clock spur (e.g., at supply port 215 and reference potential port 217 of the aggressor circuit 202 coupled to the supply node 214 and reference potential node 216, respectively). The correction circuit 402 generates replica spurs via a parallel-path open-loop clock chain, as described in more detail herein. The replica spurs may have an opposite phase as the clock spurs, thereby attenuating the clock spurs.

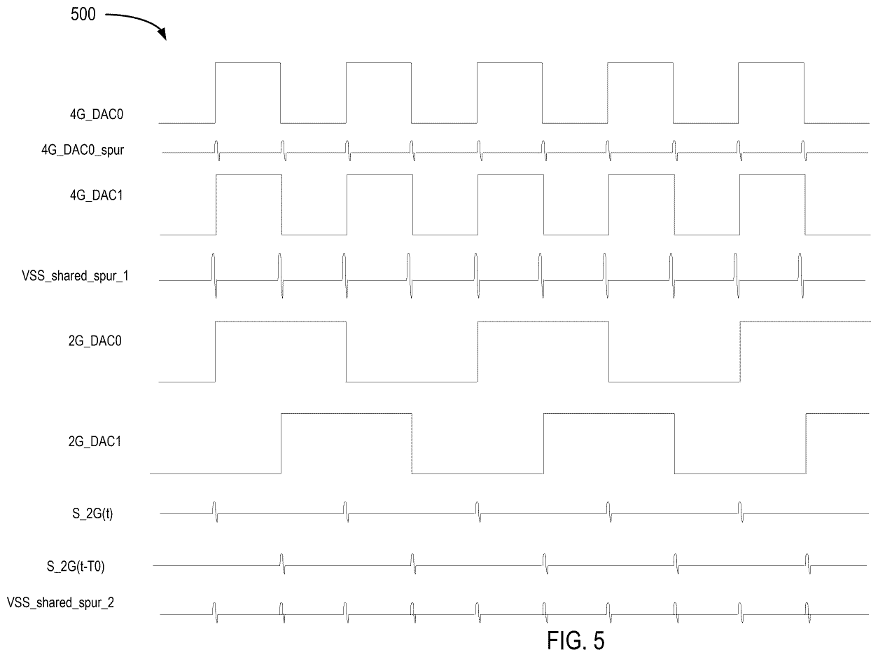

FIG. 5 is an example timing diagram 500 illustrating various clock signals and associated spurs. As shown, a first DAC (DAC0) and a second DAC (DAC1) may operate based on 4G clocks (e.g., labeled “4G_DAC0” and “4G_DAC1”). The 4G clocks may each generate clock spurs. For example, the 4G clock for DAC0 may generate clock spurs labeled “4G_DAC0_spur.” DAC0 and DAC1 may have a shared reference potential node (VSS). Thus, clock spurs (e.g., labeled “VSS_shared_spur_1”) may be generated on the shared VSS. As shown, due to the combined effect of the clocks from DAC0 and DAC1, the magnitudes of the clock spurs on the shared VSS are increased (e.g., are greater than the 4G_DAC0_spur).

As shown, in some cases, DAC0 and DAC1 may use 2G clocks (labeled “2G DAC0” and “2G_DAC1”). The 2G clocks are offset by a period TO. The 2G clocks generate clock spurs labeled “S_2G (t)” and “S_2G (t-TO),” as shown. As described, the DACs may generate clock spurs (labeled “VSS_shared_spur_2”) on a shared VSS, as shown. In the time domain, clock spurs may be generated based on the expression:

$${\sum }_{n = - ∞}^{n = + ∞} σ ( t - \frac{n}{2 Fs} )$$

where n is a positive integer, Fs is the frequency of the clock signal, and σ is the spur function. In the frequency domain, the spurs are generated based on the expression:

$${e}^{- ( j ω Δ T 0 )}$$

where ω is the angular frequency associated with the clock signals and ATO is the time offset between the clock signals, as described.

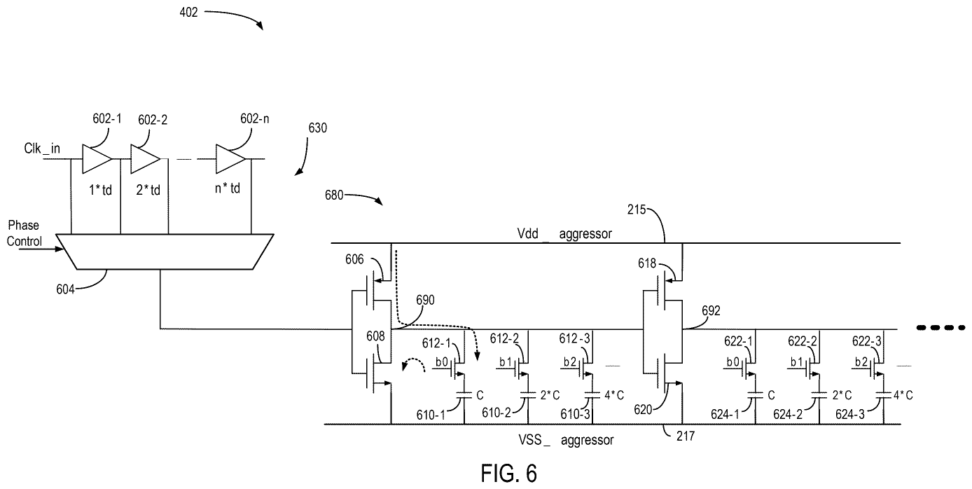

FIG. 6 illustrates an example implementation of the correction circuit 402, in accordance with certain aspects of the present disclosure. As shown, the correction circuit 402 includes a programmable delay circuit 630 to adjust the phase of the spur to be attenuated. The programmable delay circuit 630 may include delay elements 602-1, 602-2, to 602-n (collectively referred to as “delay elements 602”), n being positive integer. An input clock (Clk_in) signal may be provided to an input of delay element 602-1, where the delay elements are daisy chained (e.g., the output of delay element 602-1 is coupled to an input of delay element 602-2, and so on).

The Clk_in node and the outputs of each of the delay elements 602 may be coupled to inputs of a multiplexer 604. As shown, each of the delay elements 602 may apply a delay td. Thus, the output signal of delay element 602-1 may be the Clk_in signal delayed by td, the output signal of delay element 602-2 may be the Clk_in signal delayed by 2td, and so on. In some aspects, the programmable delay circuit 630 (e.g., delay tuning circuit) may be implemented with low load current from the Clk_in node (e.g., since the input to the multiplexer 604 and delay element 602-1 is high impedance).

During a calibration phase, the delay associated with the programmable delay circuit 630 may be selected to reduce the spur at a harmonic frequency of the clock signal. For example, during calibration, a particular phase may be selected that attenuates the spur at the second harmonic of the clock signal.

The output of the multiplexer 604 may be coupled to a power scaling circuit 680. For example, the output of the multiplexer 604 may be coupled to the gates of a p-channel metal-oxide-semiconductor (PMOS) transistor 606 and an n-channel metal-oxide-semiconductor (NMOS) transistor 608. The transistors 606, 608 form a complementary metal-oxide-semiconductor (CMOS) inverter. Based on a phase control signal (labeled “Phase Control”), the multiplexer may provide the Clk_in signal or an output signal of one of the delay elements 602 to the gates of transistors 606, 608. The source of transistor 606 may be coupled to the supply node 215 (e.g., the supply node of the aggressor circuit 202), labeled “VDD_aggressor,” as shown. The source of transistor 608 may be coupled to the reference potential node 217 (e.g., the reference potential node of the aggressor circuit 202), labeled “VSS_aggressor,” as shown.

The drains of transistors 606, 608 at node 690 are selectively coupled to capacitive elements 610-1, 610-2, 610-3 (collectively referred to as capacitive elements 610) via respective switches 612-1, 612-2, 612-3 (collectively referred to as “switches 612”). The capacitive elements 610-1, 610-2, 610-3 have capacitances C, 2C, and 4C, respectively, where C is a unit of capacitance. While three capacitive elements 610-1, 610-2, 610-3 and associated switches 612-1, 612-2, 612-3 are shown, any number of capacitive elements and associated switches may be used. By closing one or more of the switches 612, one or more respective capacitive elements 610 may be coupled between drains of the transistors 606, 608 and the reference potential node 217, setting a magnitude of the replica clock spur generated by the correction circuit 402. For example, when the output of multiplexer 604 is logic low, transistor 606 is turned on, and transistor 608 is turned off, sinking current from the supply node 214 to charge one or more of the capacitive elements 610 and generating a clock spur on the supply node 215. When the output of the multiplexer 604 is logic high, transistor 608 is turned on, and transistor 606 is turned off, discharging one or more of the capacitive elements 610 to the reference potential node 216 and generating a clock spur on the reference potential node 217. The magnitude of the generated clock spurs is based on the total capacitance of the capacitive element(s) 610 selectively coupled to drains of transistors 606, 608.

The correction circuit 402 provides a programmable delay replica clock path that generates clock spurs that are frequency locked to the aggressor circuit clock, but at a given or programmable delay to create out-of-phase clock spurs and cancel (or at least attenuate) the net clock spur from the aggressor circuit at sensitive ports (e.g., the supply node and reference potential node of the aggressor circuit). The programmable delay circuit 630 provides an open-loop delay chain. The control signal to the multiplexer 604 may be used to select a phase of the clock signal to be used for generating the replica clock spurs.

As shown, the drains of the transistors 606, 608 (e.g., output of inverter formed by transistors 606, 608) may be coupled to gates of transistors 618, 620 forming another CMOS inverter. As shown, capacitive elements 624-1, 624-2, and 624-3 (e.g., collectively referred to as “capacitive elements 624”) may be selectively coupled to drains of transistors 618, 620 at node 692 via respective switches 622-1, 622-2, and 622-3. The capacitive elements 624-1, 624-2, 624-3 have capacitances (e.g., capacitances C, 2C, and 4C) corresponding to the capacitive elements 610-1, 610-2, 610-3.

When one or more of the capacitive elements 610 are being charged via current from the supply node 214, one or more of the capacitive elements 624 are being discharged to the reference potential node. Similarly, when one or more of the capacitive elements 610 are being discharged, one or more of the capacitive elements 624 are being charged. Thus, during each rising or falling edge of the delay signal at the output of the multiplexer 604, a replica clock spur is generated on the supply node and the reference potential node.

The correction circuit allows for attenuating the power of spurs based on an emissions signature (e.g., as measured by a spectrum analyzer). The attenuation of clock spurs in a transceiver reduces constraints on output power and offers frequency planning flexibility.

### Techniques for Clock Harmonics Spur Reduction at Multiple Frequencies

The harmonics of clock signals in mixed-signal, digital, and clock-generation circuits create spurs on the supply node, reference potential node (e.g., ground node), and substrate that can couple to sensitive parts of a system on chip (SoC). The clock spurs (e.g., also referred to herein as “harmonic signals” or “spur signals”) may cause direct or mixing products such as clock harmonics. In some cases, the clock harmonics may couple to transmit and receive paths of a transceiver that can cause emission specification failure in multiple bands. The clock spurs are even more problematic in massive multiple-input multiple-output (MIMO) and devices with multiple transmitter chains where multiple aggressors (e.g., aggressor circuits) may violate multiple victims (e.g., victim circuits) with no easy way to identify the aggressors.

In some implementations, specification metrics such as error vector magnitude (EVM) may fail for one or more bands due to the clock spurs. For example, one or more harmonics of a clock signal (e.g., a clock signal for a digital-to-analog converter (DAC)) may be within the one or more operating bands causing the failure. For instance, the third and fourth harmonics of the DAC clock signal may couple to a transmitter's drive amplifier (DA) through the DA balanced-to-unbalanced (balun) ground node. This may be due to a package overlap between the balun ground node and the DAC digital circuitry.

As described herein with respect to FIG. 4, a correction circuit may be used to cancel clock spurs (harmonic signals) using replica spur signals with an opposite phase (e.g., as compared to the clock spur being canceled) via a parallel path. As used herein, canceling a clock spur generally refers to at least partly attenuating the clock spur.

In some cases, only a single spur (e.g., at a single frequency) may be attenuated, whereas other harmonic signals (e.g., spur signals) of the clock signal may cause issues at multiple frequencies or bands. Only attenuating one harmonic signal may degrade (e.g., increase the magnitude of) one or more other harmonic signals. Different delays (e.g., phases) and power levels should be used to attenuate different harmonic signals. Attenuating a third harmonic signal (e.g., at 3×a clock frequency (Fclk)) may degrade (e.g., increase) a fourth harmonic signal (e., at 4×Fclk). While attenuating the fourth harmonic signal, the tone for the third harmonic signal may degrade depending on the delay and power scaling used.

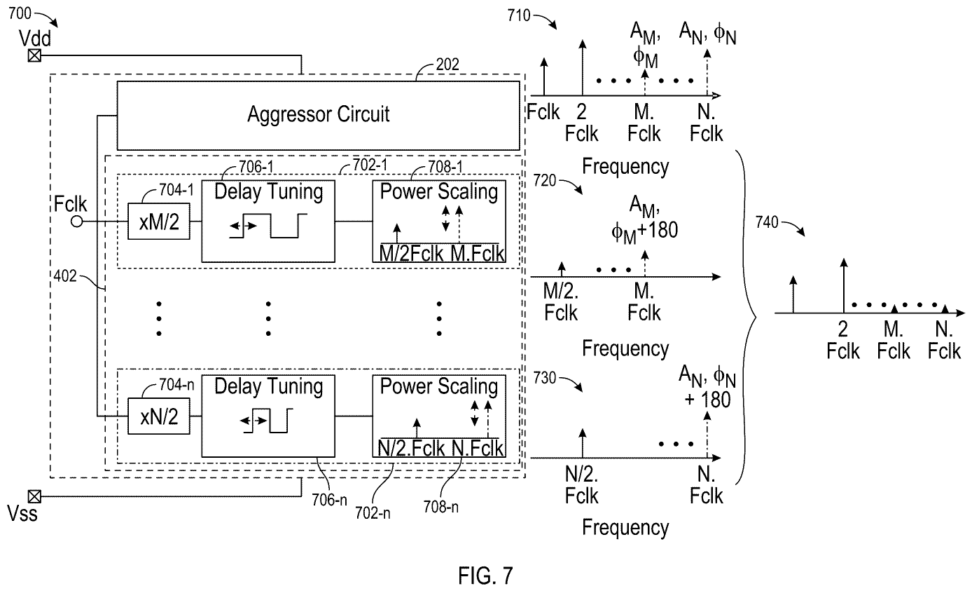

FIG. 7 illustrates a multi-path spur reduction circuit 700 using frequency multipliers, in accordance with certain aspects of the present disclosure. The circuit 700 may be used to cancel (e.g., attenuate) the harmonic signals of a clock signal (e.g., an Fclk signal) by creating replicas of each harmonic signal separately. The circuit 700 includes a separate replica spur generation path for each harmonic signal to be canceled, such as a replica spur generation path for a harmonic signal at M×Fclk and a replica spur generation path for a harmonic signal at N×Fclk, M and N being positive integers. There may be any number of replica spur generation paths to cancel any suitable number of harmonic signals. For instance, the circuit 700 may include replica spur generation paths 702-1 to 702-n (collectively referred to herein as “replica spur generation paths 702”), n being an integer corresponding to the number of harmonic signals to be canceled.

As shown, the replica spur generation paths 702 may include respective frequency multipliers 704-1 to 704-n (collectively referred to herein as “frequency multipliers 704”). Each path has a delay tuning circuit and power tuning circuit (e.g., power scaling circuit) to match (e.g., within some threshold) the spur magnitude but with an opposite phase to cancel the harmonic signal. Each of the paths 702 generates a tone at a multiple of Fclk on the supply and ground nodes. For instance, the output of the frequency multipliers may be coupled to respective inputs of delay tuning circuits 706-1 to 706-n (collectively referred to herein as “delay tuning circuits 706”). The outputs of the delay tuning circuits 706 may be coupled to respective inputs of power scaling circuits 708-1 to 708-n (e.g., collectively referred to herein as “power scaling circuits 708”).

As shown, each of the paths 702 may receive the Fclk signal. The Fclk signal may be provided to the frequency multipliers 704. Each frequency multiplier may multiply the frequency of the Fclk signal by half of an integer representing the associated harmonic frequency. For example, path 702-1 may be used to cancel a signal at a harmonic frequency of M×Fclk, where M is an integer representing the harmonic signal. For instance, M may be equal to three for the third harmonic. Thus, the frequency multiplier 704-1 may multiply Fclk by M/2. Similarly, path 702-n may be used to cancel a signal at a harmonic frequency of N× Fclk. Thus, the frequency multiplier 704-n may multiply Fclk by N/2.

The frequency-multiplied signal from each multiplier may be provided to a delay tuning circuit (e.g., delay tuning circuit 706-1) that may be used to tune the phase of the frequency-multiplied signal for spur cancellation (e.g., such that the frequency-multiplied signal has the opposite phase of the harmonic signal to be canceled). For instance, each delay tuning circuit may correspond to the delay circuit 630 described with respect to FIG. 6. However, any suitable delay circuit, such as a phase interpolator or resistor-capacitor delay cells, may be used.

The delayed signal from each of the delay tuning circuits 706 may be provided to a respective one of the power scaling circuits 708 that may be used to adjust the power of the delayed signal that is provided to the supply and ground nodes. Power scaling may be implemented using any suitable power scaling circuit. For example, power scaling may be implemented by enabling or disabling one or more buffers. In some cases, each of the power scaling circuits 708 may correspond to the power scaling circuit 680 described with respect to FIG. 6. For example, the source of transistor 606 and the source of transistor 608 may be the outputs of the power scaling circuit 680 to generate replica spur signals at the supply node (Vdd) and the reference potential node (Vss).

The level of delay and power scaling applied may be set using any suitable technique. The delay and power of each path may be adjusted while monitoring the magnitude of the associated harmonic signal (e.g., spur signal) in order to reduce the magnitude of the harmonic signal. In some cases, each path may be tuned separately. For example, path 702-1 may be tuned first, followed by path 702-n.

The graph 710 shows the magnitude of the Fclk signal and 2×Fclk signal (e.g., the second harmonic of the Fclk signal). As shown, an aggressor spur signal is generated at M×Fclk (labeled “M.Fclk”) and at N×Fclk (e.g., labeled “N.Fclk”). The graph 720 shows the frequency-multiplied signal at M/2×Fclk (labeled “M/2.Fclk”) and the replica spur at M×Fclk (labeled “M.Fclk”) generated by the path 702-1. The graph 730 shows the frequency-multiplied signal at N/2×Fclk (labeled “N/2.Fclk”) and the replica spur signal at N×Fclk (labeled “N.Fclk”) generated by the path 702-n. The replica spurs from the paths 702 may be combined with the aggressor spur signal at the supply and ground nodes, reducing spur signals at M×Fclk and N×Fclk, as shown in graph 740. That is, the magnitude of the aggressor spur signals is reduced due to the opposite phase of each replica spur signal compared to the associated aggressor spur signal.

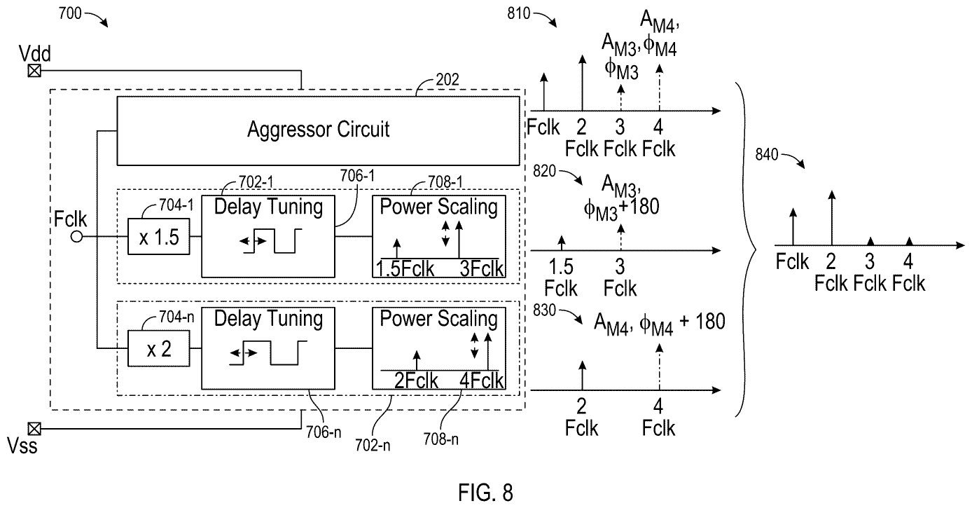

FIG. 8 illustrates the multi-path spur reduction circuit 700 using frequency multipliers to cancel third and fourth harmonic signals, in accordance with certain aspects of the present disclosure. As shown, the frequency multiplier 704-1 may multiply the Fclk signal by 1.5 (e.g., M/2 where M is equal to 3) to cancel the third harmonic signal. The frequency multiplier 704-n may multiply the Fclk signal by 2 (e.g., N/2 where N is equal to 4) to cancel the fourth harmonic signal. The frequency-multiplied signals may be tuned using delay tuning and power scaling to cancel the third and fourth harmonic signals.

As shown in graph 810, the third harmonic (3Fclk) of the aggressor spur signal may have a magnitude of A_{M3} and a phase of Φ_{M3} and the fourth harmonic (4Fclk) of the aggressor spur signal may have a magnitude of A_{M4} and a phase of Φ_{M4}. As shown in graph 820, the replica spur signal for canceling the third harmonic signal may have a magnitude of A_{M3} and a phase of Φ_{M3}+180. As shown in graph 830, the replica spur signal for canceling the fourth harmonic signal may have a magnitude of A_{M4} and a phase of Φ_{M4}+180. As shown in graph 840, each of the replica spur signals from the paths 702 may be combined with a respective aggressor spur signal at the supply and ground nodes, reducing the spur signals at 3Fclk and 4Fclk.

In some cases, the paths 702 may be implemented to cancel harmonic signals that are not integer multiples of each other. For example, if a first path is used to cancel the third harmonic (e.g., at 3×Fclk) and a second path is used to cancel the sixth harmonic (e.g., at 6×Fclk), since 3 and 6 are integer multiples, the first and second paths may interfere with each other. The first path may generate replica spurs at 3×Fclk, 6×Fclk, 9×Fclk, and so on. The second path may generate replica spurs at 6×Fclk, 12×Fclk, and so on. Therefore, the replica spur signal at 6×Fclk generated via the first path may impact the replica spur signal at 6×Fclk generated via the second path. However, the spur reduction circuit described herein may be implemented with multiple paths where the paths are used to cancel harmonic signals that are integer multiples (e.g., third and sixth harmonics). In this case, the paths 702 may be tuned together to cancel the harmonic signals given the impact from one path to another.

As described with respect to FIG. 8, two individual cancellation paths (e.g., paths 702) may be used with input frequencies of 1.5×Fclk and 2×Fclk to cancel the third and fourth harmonics. The first path (e.g., 1.5×Fclk path) may inject harmonic signals (e.g., replica spur signal) at 3×Fclk to the supply node and the reference potential node. The second path (e.g., 2×Fclk path) may inject harmonic signals (e.g., replica spur signal) at 4×Fclk to the supply node and the reference potential node. Thus, the two paths may operate in parallel to cancel both 3×Fclk and 4×Fclk spur signals without interrupting each other.

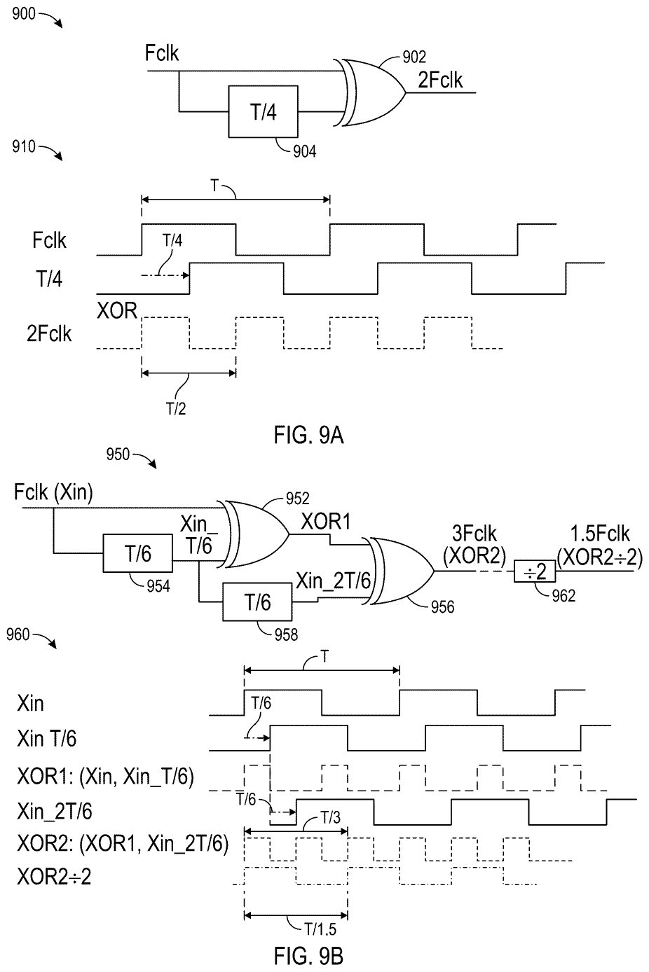

FIG. 9A illustrates a frequency multiplier 900 for multiplying a frequency of a signal by two, in accordance with certain aspects of the present disclosure. The multiplier 900 may include an exclusive OR (XOR) gate 902 with a first input receiving an Fclk signal and a second input receiving the Fclk signal through a delay element 904. The delay element 904 may apply a delay of T/4, T being the period of the Fclk signal as shown in timing diagram 910. The XOR gate 902 may generate a signal with a frequency of 2Fclk (e.g., with a period of T/2 as shown in timing diagram 910).

FIG. 9B illustrates a frequency multiplier 950 for multiplying a frequency of a signal by 3 or 1.5, in accordance with certain aspects of the present disclosure. As shown, the frequency multiplier 950 may include an XOR gate 952 with a first input receiving the Fclk signal (e.g., also referred to as “Xin” signal) and a second input receiving the Fclk signal through a delay element 954. The delay element 954 applies a delay of T/6, T being the period of the Fclk signal (Xin signal), to generate a delayed signal (Xin_T/6) as shown in timing diagram 960. The output of the XOR gate 952 provides an output signal (XOR1) as shown in timing diagram 960 and is coupled to a first input of an XOR gate 956. A second input of the XOR gate 956 receives the Xin_T/6 signal through another delay element 958. The delay element 958 applies a delay of T/6, T being the period of the Fclk signal (Xin signal), to generate another delayed signal (Xin_2T/6) as shown in timing diagram 960. The output of the XOR gate 956 provides an output signal (XOR2) at 3×Fclk and is coupled to an input of a frequency divider 962 (e.g., divide-by-2 frequency divider) to generate the 1.5×Fclk signal.

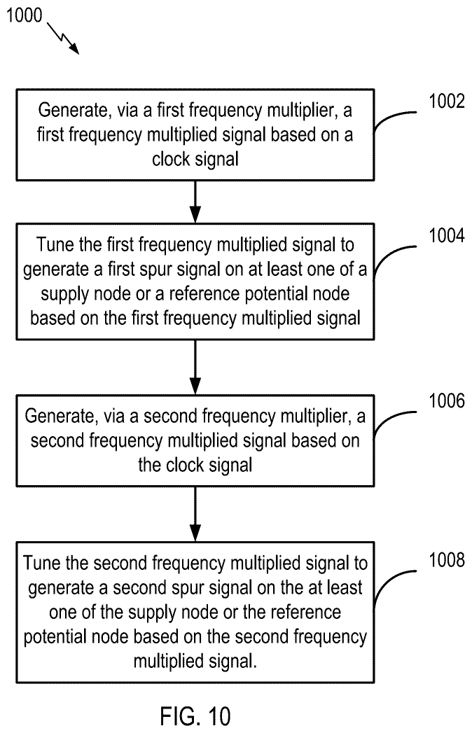

FIG. 10 illustrates example operations 1000 for signal processing, in accordance with certain aspects of the present disclosure. The operations 1000 may be performed by a spur reduction circuit, such as the spur reduction circuit 700 of FIG. 7.

At block 1002, the spur reduction circuit may generate, via a first frequency multiplier (e.g., frequency multiplier (704-1), a first frequency-multiplied signal based on a clock signal (e.g., Fclk signal). At block 1004, the spur reduction circuit may tune the first frequency-multiplied signal to generate a first spur signal (e.g., M.Fclk signal shows in graph 720 of FIG. 7) on at least one of a supply node (e.g., Vdd) or a reference potential node (e.g., electric ground node) based on the first frequency-multiplied signal.

At block 1006, the spur reduction circuit may generate, via a second frequency multiplier (e.g., frequency multiplier 704-n), a second frequency-multiplied signal based on the clock signal. At block 1008, the spur reduction circuit may tune the second frequency-multiplied signal to generate a second spur signal (e.g., N.Fclk signal shown graph 730 of FIG. 7) on the at least one of the supply node or the reference potential node based on the second frequency-multiplied signal.

In some aspects, the first spur signal may replicate a spur associated with the clock signal but with a first phase offset, and the second spur signal may replicate another spur associated with the clock signal but with a second phase offset. For example, the first spur signal may be 180° out-of-phase with a first spur generated on the supply node or the reference potential node by the clock signal, and the second spur signal may be 180° out-of-phase with a second spur generated on the supply node or the reference potential node by the clock signal.

In some aspects, generating the first frequency-multiplied signal may include multiplying a frequency of the clock signal by a first value, and generating the second frequency-multiplied signal may include multiplying the frequency of the clock signal by a second value different than the first value. For example, a first integer (e.g., M) may represent a harmonic of the clock signal, the first value being equal to the first integer divided by two. A second integer (e.g., N) may represent another harmonic of the clock signal, the second value being equal to the second integer divided by two.

In some aspects, tuning the first frequency-multiplied signal may include applying, via a first delay element (e.g., delay tuning circuit 706-1), a delay to the first frequency-multiplied signal to generate a first delayed signal, and tuning the second frequency-multiplied signal may include applying, via a second delay element (e.g., via delay element 706-n), a delay to the second frequency-multiplied signal to generate a second delayed signal.

Tuning the first frequency-multiplied signal may include adjusting a phase of the first frequency-multiplied signal to generate the first delayed signal, and tuning the second frequency-multiplied signal may include adjusting a phase of the second frequency-multiplied signal to generate the second delayed signal. In some aspects, the phase of the first frequency-multiplied signal is adjusted by 180°, and the phase of the second frequency-multiplied signal is adjusted by 180°. In some aspects, tuning the first frequency-multiplied signal may also include adjusting a power (e.g., via the power scale element 708-1) of the first delayed signal to generate the first spur signal and tuning the second frequency-multiplied signal may also include adjusting a power (e.g., via the power scale element 708-n) of the second delayed signal to generate the second spur signal.

In some aspects, generating the first frequency-multiplied signal may include applying a delay (e.g., via the delay element 904 or 954) to the clock signal to generate a first delayed signal, and performing, via an XOR gate (e.g., XOR gate 902 or 952), an XOR operation on the clock signal and the first delayed signal. In some aspects, generating the first frequency-multiplied signal may include applying a delay (e.g., via the delay element 958) to the first delayed signal to generate a second delayed signal, and performing, via another XOR gate (e.g., XOR gate 956), another XOR operation on an output signal of the XOR gate and the second delayed signal. In some aspects, generating the first frequency-multiplied signal may include frequency dividing an output signal of the other XOR gate.

### Example Aspects

In addition to the various aspects described above, specific combinations of aspects are within the scope of the disclosure, some of which are detailed below:

Aspect 1: An apparatus for signal processing, comprising: a first signal generation path including a first frequency multiplier having an input coupled to a clock node and at least one first tuning circuit coupled to an output of the first frequency multiplier, the at least one first tuning circuit including outputs coupled to a supply node and a reference potential node of the apparatus; and a second signal generation path including a second frequency multiplier having an input coupled to the clock node and at least one second tuning circuit coupled to an output of the second frequency multiplier, the at least one second tuning circuit including outputs coupled to the supply node and the reference potential node of the apparatus.

Aspect 2: The apparatus of Aspect 1, wherein: the at least one first tuning circuit is configured to generate a first spur signal that is 180° out-of-phase with a first spur generated on the supply node or the reference potential node by a clock signal at the clock node; and the at least one second tuning circuit is configured to generate a second spur signal that is 180° out-of-phase with a second spur generated on the supply node or the reference potential node by the clock signal at the clock node.

Aspect 3: The apparatus of Aspect 1 or 2, wherein: the first frequency multiplier is configured to multiple a frequency of a clock signal at the clock node by a first value; and the second frequency multiplier is configured to multiple the frequency of the clock signal by a second value different than the first value.

Aspect 4: The apparatus of Aspect 3, wherein: a first integer represents a harmonic of the clock signal, the first value being equal to the first integer divided by two; and a second integer represents another harmonic of the clock signal, the second value being equal to the second integer divided by two.

Aspect 5: The apparatus according to any of Aspects 1-4, wherein: the at least one first tuning circuit includes a first delay element with an input coupled to the output of the first frequency multiplier; and the at least one second tuning circuit includes a second delay element with an input coupled to the output of the second frequency multiplier.

Aspect 6: The apparatus of Aspect 5, wherein: the first frequency multiplier is configured to generate a first frequency-multiplied signal based on a clock signal at the clock node, the at least one first tuning circuit being configured to adjust a phase of the first frequency-multiplied signal; and the second frequency multiplier is configured to generate a second frequency-multiplied signal based on the clock signal at the clock node, the at least one second tuning circuit being configured to adjust a phase of the second frequency-multiplied signal.

Aspect 7: The apparatus of Aspect 6, wherein: the at least one first tuning circuit is configured to adjust the phase of the first frequency-multiplied signal by 180°; and the at least one second tuning circuit is configured to adjust the phase of the second frequency-multiplied signal by 180°.

Aspect 8: The apparatus according to any of Aspects 5-7, wherein: the at least one first tuning circuit includes a first power scaling circuit with an input coupled to an output of the first delay element; and the at least one second tuning circuit includes a second power scaling circuit with an input coupled to an output of the second delay element.

Aspect 9: The apparatus according to any of Aspects 1-8, wherein: the at least one first tuning circuit is configured to generate a first replica spur signal that replicates a spur associated with a clock signal at the clock node but with a first phase offset; and the at least one second tuning circuit is configured to generate a second replica spur signal that replicates another spur associated with the clock signal at the clock node but with a second phase offset.

Aspect 10: The apparatus according to any of Aspects 1-9, wherein the first frequency multiplier comprises: a first exclusive OR (XOR) gate with a first input coupled to the clock node; and a first delay element coupled between a second input of the first XOR gate and the clock node.

Aspect 11: The apparatus of Aspect 10, wherein the first frequency multiplier further comprises: a second XOR gate with a first input coupled to an output of the first XOR gate; and a second delay element coupled between an output of the first delay element and a second input of the second XOR gate.

Aspect 12: The apparatus of Aspect 11, wherein the first frequency multiplier further comprises a frequency divider coupled between an output of the first frequency multiplier and an output of the second XOR gate.

Aspect 13: A method for signal processing, comprising: generating, via a first frequency multiplier, a first frequency-multiplied signal based on a clock signal; tuning the first frequency-multiplied signal to generate a first spur signal on at least one of a supply node or a reference potential node based on the first frequency-multiplied signal; generating, via a second frequency multiplier, a second frequency-multiplied signal based on the clock signal; and tuning the second frequency-multiplied signal to generate a second spur signal on the at least one of the supply node or the reference potential node based on the second frequency-multiplied signal.

Aspect 14: The method of Aspect 13, wherein: the first spur signal is 180° out-of-phase with a first spur generated on the supply node or the reference potential node by the clock signal; and the second spur signal is 180° out-of-phase with a second spur generated on the supply node or the reference potential node by the clock signal.

Aspect 15: The method of Aspect 13 or 14, wherein: the first spur signal replicates a spur associated with the clock signal but with a first phase offset; and the second spur signal replicates another spur associated with the clock signal but with a second phase offset.

Aspect 16: The method according to any of Aspects 13-15, wherein: generating the first frequency-multiplied signal comprises multiplying a frequency of the clock signal by a first value; and generating the second frequency-multiplied signal comprises multiplying the frequency of the clock signal by a second value different than the first value.

Aspect 17: The method of Aspect 16, wherein: a first integer represents a harmonic of the clock signal, the first value being equal to the first integer divided by two; and a second integer represents another harmonic of the clock signal, the second value being equal to the second integer divided by two.

Aspect 18: The method according to any of Aspects 13-17, wherein: tuning the first frequency-multiplied signal comprises applying, via a first delay element, a first delay to the first frequency-multiplied signal to generate a first delayed signal; and tuning the second frequency-multiplied signal comprises applying, via a second delay element, a second delay to the second frequency-multiplied signal to generate a second delayed signal.

Aspect 19: The method of Aspect 18, wherein: tuning the first frequency-multiplied signal comprises adjusting a phase of the first frequency-multiplied signal; and tuning the second frequency-multiplied signal comprises adjusting a phase of the second frequency-multiplied signal.

Aspect 20: The method of Aspect 19, wherein: the phase of the first frequency-multiplied signal is adjusted by 180°; and the phase of the second frequency-multiplied signal is adjusted by 180°.

Aspect 21: The method according to any of Aspects 18-20, wherein: tuning the first frequency-multiplied signal further comprises adjusting a power of the first delayed signal to generate the first spur signal; and tuning the second frequency-multiplied signal further comprises adjusting a power of the second delayed signal to generate the second spur signal.

Aspect 22: The method according to any of Aspects 13-21, wherein generating the first frequency-multiplied signal comprises: applying a delay to the clock signal to generate a first delayed signal; and performing, via an exclusive OR (XOR) gate, an XOR operation on the clock signal and the first delayed signal.

Aspect 23: The method of Aspect 22, wherein generating the first frequency-multiplied signal comprises: applying a delay to the first delayed signal to generate a second delayed signal; and performing, via another XOR gate, another XOR operation on an output signal of the XOR gate and the second delayed signal.

Aspect 24: The method of Aspect 23, wherein generating the first frequency-multiplied signal comprises frequency dividing an output signal of the other XOR gate.

Aspect 25: An electronic device, comprising: an electronic circuit coupled between a supply node and a reference potential node and configured to perform one or more operations using a clock signal at a clock node; and a spur reduction circuit comprising: a first signal generation path including a first frequency multiplier having an input coupled to the clock node and at least one first tuning circuit coupled to an output of the first frequency multiplier, the at least one first tuning circuit including outputs coupled to a supply node and a reference potential node of the electronic device; and a second signal generation path including a second frequency multiplier having an input coupled to the clock node and at least one second tuning circuit coupled to an output of the second frequency multiplier, the at least one second tuning circuit including outputs coupled to the supply node and the reference potential node of the electronic device.

### ADDITIONAL CONSIDERATIONS

The various operations of methods described above may be performed by any suitable means capable of performing the corresponding functions. The means may include various hardware and/or software component(s) and/or module(s), including, but not limited to a circuit, an application-specific integrated circuit (ASIC), or a processor. Generally, where there are operations illustrated in figures, those operations may have corresponding counterpart means-plus-function components with similar numbering.

As used herein, the term “determining” encompasses a wide variety of actions. For example, “determining” may include calculating, computing, processing, deriving, investigating, looking up (e.g., looking up in a table, a database, or another data structure), ascertaining, and the like. Also, “determining” may include receiving (e.g., receiving information), accessing (e.g., accessing data in a memory), and the like. Also, “determining” may include resolving, selecting, choosing, establishing, and the like.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

It is to be understood that the claims are not limited to the precise configuration and components illustrated above. Various modifications, changes, and variations may be made in the arrangement, operation, and details of the methods and apparatus described above without departing from the scope of the claims.

What is claimed is:

1. An apparatus for signal processing, comprising:
a first signal generation path including a first frequency multiplier having an input coupled to a clock node and at least one first tuning circuit coupled to an output of the first frequency multiplier, the at least one first tuning circuit including outputs coupled to a supply node and a reference potential node of the apparatus; and
a second signal generation path including a second frequency multiplier having an input coupled to the clock node and at least one second tuning circuit coupled to an output of the second frequency multiplier, the at least one second tuning circuit including outputs coupled to the supply node and the reference potential node of the apparatus.

2. The apparatus of claim 1, wherein:
the at least one first tuning circuit is configured to generate a first spur signal that is 180° out-of-phase with a first spur generated on the supply node or the reference potential node by a clock signal at the clock node; and
the at least one second tuning circuit is configured to generate a second spur signal that is 180° out-of-phase with a second spur generated on the supply node or the reference potential node by the clock signal at the clock node.

3. The apparatus of claim 1, wherein:
the first frequency multiplier is configured to multiple a frequency of a clock signal at the clock node by a first value; and
the second frequency multiplier is configured to multiple the frequency of the clock signal by a second value different than the first value.

4. The apparatus of claim 3, wherein:
a first integer represents a harmonic of the clock signal, the first value being equal to the first integer divided by two; and
a second integer represents another harmonic of the clock signal, the second value being equal to the second integer divided by two.

5. The apparatus of claim 1, wherein:
the at least one first tuning circuit includes a first delay element with an input coupled to the output of the first frequency multiplier; and
the at least one second tuning circuit includes a second delay element with an input coupled to the output of the second frequency multiplier.

6. The apparatus of claim 5, wherein:
the first frequency multiplier is configured to generate a first frequency-multiplied signal based on a clock signal at the clock node, the at least one first tuning circuit being configured to adjust a phase of the first frequency-multiplied signal; and
the second frequency multiplier is configured to generate a second frequency-multiplied signal based on the clock signal at the clock node, the at least one second tuning circuit being configured to adjust a phase of the second frequency-multiplied signal.

7. The apparatus of claim 6, wherein:
the at least one first tuning circuit is configured to adjust the phase of the first frequency-multiplied signal by 180°; and
the at least one second tuning circuit is configured to adjust the phase of the second frequency-multiplied signal by 180°.

8. The apparatus of claim 5, wherein:
the at least one first tuning circuit includes a first power scaling circuit with an input coupled to an output of the first delay element; and
the at least one second tuning circuit includes a second power scaling circuit with an input coupled to an output of the second delay element.

9. The apparatus of claim 1, wherein:
the at least one first tuning circuit is configured to generate a first replica spur signal that replicates a spur associated with a clock signal at the clock node but with a first phase offset; and
the at least one second tuning circuit is configured to generate a second replica spur signal that replicates another spur associated with the clock signal at the clock node but with a second phase offset.

10. The apparatus of claim 1, wherein the first frequency multiplier comprises:
a first exclusive OR (XOR) gate with a first input coupled to the clock node; and
a first delay element coupled between a second input of the first XOR gate and the clock node.

11. The apparatus of claim 10, wherein the first frequency multiplier further comprises:
a second XOR gate with a first input coupled to an output of the first XOR gate; and
a second delay element coupled between an output of the first delay element and a second input of the second XOR gate.

12. The apparatus of claim 11, wherein the first frequency multiplier further comprises a frequency divider coupled between an output of the first frequency multiplier and an output of the second XOR gate.

13. A method for signal processing, comprising:
generating, via a first frequency multiplier, a first frequency-multiplied signal based on a clock signal;
tuning the first frequency-multiplied signal to generate a first spur signal on at least one of a supply node or a reference potential node based on the first frequency-multiplied signal;
generating, via a second frequency multiplier, a second frequency-multiplied signal based on the clock signal; and
tuning the second frequency-multiplied signal to generate a second spur signal on the at least one of the supply node or the reference potential node based on the second frequency-multiplied signal.

14. The method of claim 13, wherein:
the first spur signal is 180° out-of-phase with a first spur generated on the supply node or the reference potential node by the clock signal; and
the second spur signal is 180° out-of-phase with a second spur generated on the supply node or the reference potential node by the clock signal.

15. The method of claim 13, wherein:
the first spur signal replicates a spur associated with the clock signal but with a first phase offset; and
the second spur signal replicates another spur associated with the clock signal but with a second phase offset.

16. The method of claim 13, wherein:
generating the first frequency-multiplied signal comprises multiplying a frequency of the clock signal by a first value; and
generating the second frequency-multiplied signal comprises multiplying the frequency of the clock signal by a second value different than the first value.

17. The method of claim 16, wherein:
a first integer represents a harmonic of the clock signal, the first value being equal to the first integer divided by two; and
a second integer represents another harmonic of the clock signal, the second value being equal to the second integer divided by two.

18. The method of claim 13, wherein:
tuning the first frequency-multiplied signal comprises applying, via a first delay element, a first delay to the first frequency-multiplied signal to generate a first delayed signal; and
tuning the second frequency-multiplied signal comprises applying, via a second delay element, a second delay to the second frequency-multiplied signal to generate a second delayed signal.

19. The method of claim 18, wherein:
tuning the first frequency-multiplied signal comprises adjusting a phase of the first frequency-multiplied signal; and
tuning the second frequency-multiplied signal comprises adjusting a phase of the second frequency-multiplied signal.

20. An electronic device, comprising:
an electronic circuit coupled between a supply node and a reference potential node and configured to perform one or more operations using a clock signal at a clock node; and
a spur reduction circuit comprising:
a first signal generation path including a first frequency multiplier having an input coupled to the clock node and at least one first tuning circuit coupled to an output of the first frequency multiplier, the at least one first tuning circuit including outputs coupled to a supply node and a reference potential node of the electronic device; and
a second signal generation path including a second frequency multiplier having an input coupled to the clock node and at least one second tuning circuit coupled to an output of the second frequency multiplier, the at least one second tuning circuit including outputs coupled to the supply node and the reference potential node of the electronic device.
